(19) United States
(12) Patent Application Publication
(10) Pub. No.: US 2024/0175943 A1
(43) Pub. Date: May 30, 2024

(54) CONNECTION CONTROL CIRCUIT, AND CONNECTION CONTROL METHOD

(71) Applicant: Renesas Electronics Corporation, Tokyo (JP)

(72) Inventor: Takayuki SUZUKI, Tokyo (JP)

(21) Appl. No.: 18/518,327

(22) Filed: Nov. 22, 2023

(30) Foreign Application Priority Data
Nov. 24, 2022 (JP) 2022-187027

(51) Int. Cl. G01R 31/66; G01R 19/00; H03K 5/24

(52) U.S. Cl. CPC G01R 31/66; G01R 19/0038; H03K 5/24

(57) ABSTRACT

A connection control circuit according to an embodiment includes an operation mode detection circuit having an operation state control circuit. In a first state in which an other device is not connected to a first device, the operation state control circuit sets the receiver circuit to an operating state and the operation mode detection circuit to a stopped state. In addition, in a second state in which the other device is connected to the first device, the operation state control circuit sets the receiver circuit to a stopped state and the operation mode detection circuit to an operating state.

### CROSS-REFERENCE TO RELATED APPLICATIONS

The disclosure of Japanese Patent Application No. 2022-187027 filed on Nov. 24, 2022 including the specification, drawings and abstract is incorporated herein by reference in its entirety.

### BACKGROUND

The present invention relates to a connection control circuit and a connection control method, and particularly relates to, for example, a connection control circuit conforming to the USB Type-C standard and a connection control method using such a connection control circuit.

There is disclosed a technique listed below. [Non-Patent Document 1] “Universal Serial Bus Type-C Cable and Connector Specification”, Release 2.1, May 2021.

A USB (Universal Serial Bus) connector compliant with the USB Type-C standard (see Non-Patent Document 1) is smaller than a connector compliant with the USB Type-A standard, and is more convenient since it does not require a distinction between the front and back sides. In addition, the USB Type-C standard allows more power to be supplied and received to and from a VBUS power supply.

The USB Type-C standard does not require a distinction in the connector shape. Therefore, when two devices are connected using a connector, it is necessary determine a side supplying power (hereinafter also referred to as “source side”) and a side receiving power (hereinafter also referred to as “sink side”). Such an operation is performed by a connection control circuit (hereinafter also referred to as “CCPHY”) of a USB controller. Specifically, the CCPHY can determine whether an own device is the source side or the sink side by detecting states of a CC1 terminal and a CC2 terminal for a configuration channel.

As described above, the CCPHY can determine whether the own device is the source side or the sink side by detecting states of the CC1 terminal and the CC2 terminal. Specifically, the CCPHY detects voltages of the CC1 terminal and the CC2 (hereinafter also collectively referred to as CC terminal terminal), and detects an operation mode (that is, a source mode or a sink mode) of the own device based on the detected voltage of the CC terminal.

Here, the voltage of the CC terminal is detected by utilizing a detection circuit configured using a comparator. However, such a detection circuit continues to consume a predetermined amount of power in its standby mode. Therefore, a problem arises in that power consumption of the CCPHY would become large in an unconnected state.

Other problems and novel features will become apparent from the description in the present specification and accompanying drawings.

### SUMMARY

A connection control circuit according to one embodiment includes: a CC terminal; an operation mode detection circuit configured to detect an operation mode of an own device based on a voltage of a first node connected to the CC terminal; a receiver circuit connected in parallel to the operation mode detection circuit and configured to receive the voltage of the first node; a voltage change detection circuit configured to detect a change in a voltage level output from the receiver circuit; and an operation state control circuit configured to control operation states of the operation mode detection circuit and the receiver circuit according to a detection result of the voltage change detection circuit. In a first state in which an other device is not connected to the own device, the operation state control circuit sets the receiver circuit to an operating state and the operation mode detection circuit to a stopped state. In a second state in which the other device is connected to the own device and the voltage change detection circuit has detected a change in the voltage level output from the receiver circuit, the operation state control circuit sets the receiver circuit to a stopped state and the operation mode detection circuit to an operating state. In the second state, the operation mode detection circuit detects the operation mode of the own device based on the voltage of the first node.

According to the above-described embodiment, it is possible to provide a connection control circuit and a connection control method capable of reducing power consumption when not connected.

### BRIEF DESCRIPTION OF THE DRAWINGS

FIG. 1 is a circuit diagram for describing a related art.

FIG. 2 is a flowchart for describing an operation of the related art.

FIG. 3 is a circuit diagram showing a configuration example of a connection control circuit according to a first embodiment.

FIG. 4 is a flowchart for describing an operation of the connection control circuit according to the first embodiment.

FIG. 5 is a flowchart for describing the operation of the connection control circuit according to the first embodiment.

FIG. 6 is a circuit diagram showing a configuration example of a connection control circuit according to a second embodiment.

FIG. 7 is a circuit diagram showing a configuration example of a transceiver.

FIG. 8 is a flowchart for describing an operation of the connection control circuit according to the second embodiment.

FIG. 9 is a flowchart for describing the operation of the connection control circuit according to the second embodiment.

### DETAILED DESCRIPTION

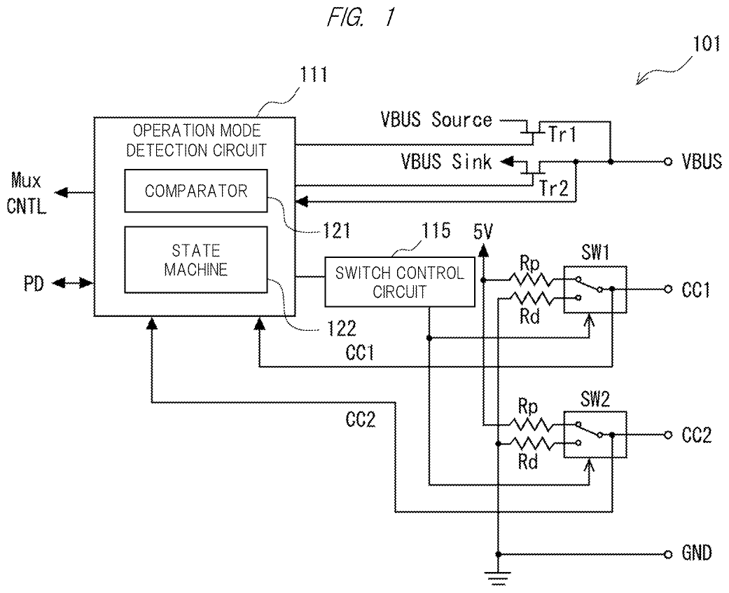

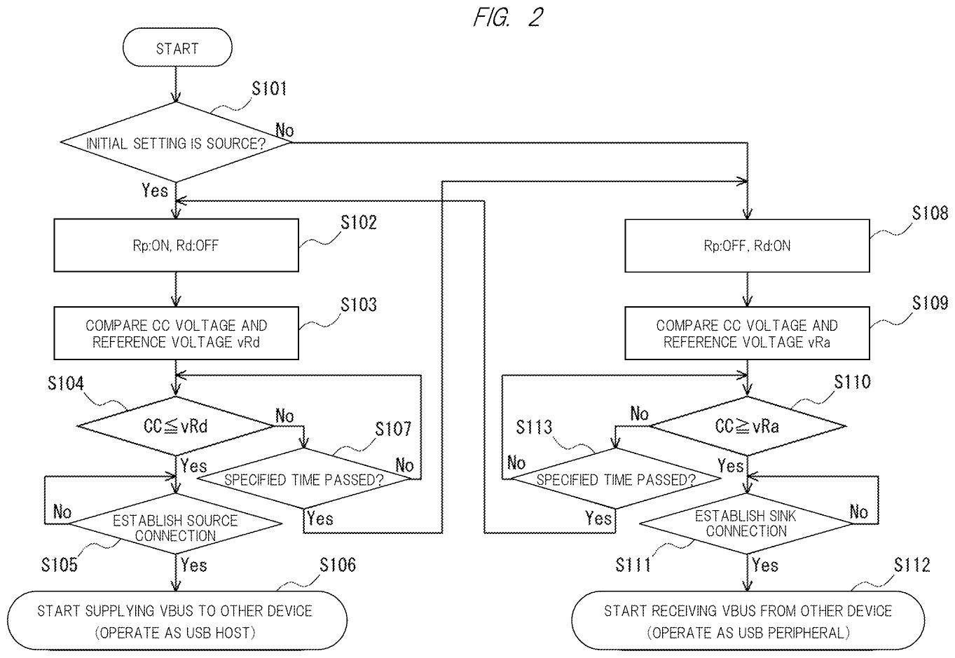

First, problems of a related art will be described. FIG. 1 is a circuit diagram for describing the related art. FIG. 1 corresponds to a CCPHY configuration described in Non-Patent Document 1, and is a circuit diagram created by the inventor with minor changes made to illustrate the problems of the related art. FIG. 2 is a flowchart for describing an operation of the related art.

As shown in FIG. 1, a connection control circuit (CCPHY) 101 according to the related art comprises a VBUS terminal, a CC1 terminal, a CC2 terminal, a GND terminal, switching circuits SW1 and SW2, a pull-up resistor Rp, a pull-down resistor Rd, an operation mode detection circuit 111, a switch control circuit 115, and transistors Tr1 and Tr2.

The CC1 terminal is connected to one end of the pull-up resistor Rp or one end of the pull-down resistor Rd via the switching circuit SW1. The other end of the pull-up resistor Rp is connected to a power supply potential (5V). The other end of the pull-down resistor Rd is connected to a ground potential (GND). Information regarding a voltage CC1 of the CC1 terminal is supplied to the operation mode detection circuit 111.

Likewise, the CC2 terminal is connected to one end of the pull-up resistor Rp or one end of the pull-down resistor Rd via the switching circuit SW2. The other end of the pull-up resistor Rp is connected to the power supply potential (5V). The other end of the pull-down resistor Rd is connected to the ground potential (GND). Information regarding a voltage CC2 of the CC2 terminal is supplied to the operation mode detection circuit 111. Thus, the pull-up resistor Rp, the pull-down resistor Rd, and the switching circuits SW1 and SW2 are provided so as to correspond to each of the CC1 terminal and the CC2 terminal. That is, the connector is reversible in the USB Type-C standard. Therefore, when an own device and an other device are connected using a USB cable, the CC1 terminal or the CC2 terminal of the own device is configured to be connected to the CC1 terminal or the CC2 terminal of the other device. Such a configuration allows the connector to be reversible. Furthermore, the term “own device (first device)” refers to a device equipped with a Connection Control Circuit (CCPHY) 101, while “other device (second device)” refers to the counterpart device connected via a USB cable to the own device.

The switch control circuit 115 controls the switching circuit SW1 and the switching circuit SW2 according to controls of the operation mode detection circuit 111. Specifically, if the own device operates as a source, the switch control circuit 115 controls the switching circuits SW1 and SW2 such that the CC1 terminal and the CC2 terminal are connected to the pull-up resistor Rp. In addition, if the own device operates as a sink, the switch control circuit 115 controls the switching circuits SW1 and SW2 such that the CC1 terminal and the CC2 terminal are connected to the pull-down resistor Rd.

The operation mode detection circuit 111 comprises a comparator 121 and a state machine 122. When the own device and the other device are connected using a USB cable, the operation mode detection circuit 111 uses the comparator 121 to detect a voltage level of the CC1 terminal or the CC2 terminal (hereinafter referred to as “CC terminal”). Information regarding the voltage level of the CC terminal detected by the comparator 121 is supplied to the state machine 122. The state machine 122 determines an operation mode of the own device according to the voltage level of the CC terminal.

If the operation mode of the own device is the source mode, the operation mode detection circuit 111 sets the transistor Tr1 to an ON state and the transistor Tr2 to an OFF state and connects the VBUS terminal and a VBUS source to supply power. On the other hand, if the operation mode of the own device is the sink mode, the operation mode detection circuit 111 sets the transistor Tr2 to the ON state and the transistor Tr1 to the OFF state and connects the VBUS terminal and a VBUS sink. Note that details of a process to determine the operation mode are defined in Non-Patent Document 1.

The operation of the related art will now be described with reference to the flowchart shown in FIG. 2. FIG. 2 shows the operation in a case where the connection control circuit (CCPHY) 101 operates in a DRP (Dual Role Power) mode. The DRP mode is a mode in which the own device can selectively operate as the source or the sink.

First, the connection control circuit 101 confirms an initial setting of the connection control circuit 101 of the own device. If the initial setting of the connection control circuit 101 is the source (step S101: Yes), the switch control circuit 115 controls the switching circuits SW1 and SW2 such that the CC1 terminal and the CC2 terminal are connected to the pull-up resistor Rp (step S102).

Next, the comparator 121 of the operation mode detection circuit 111 compares the voltage (CC voltage) of the CC terminal and a reference voltage vRd (step S103). Here, the reference voltage vRd is used to determine that the own device is the source, and details thereof are defined in Non-Patent Document 1.

If the condition of CC voltage ≤ vRd is satisfied (step S104: Yes), that is, if the own device and the other device are connected using a USB cable, and if the operation mode of the other device is the sink mode, a source connection is established (step S105: Yes). Note that the operation mode of the other device is the sink mode when the CC terminal of the other device is connected to the pull-down resistor Rd.

Once the source connection is established, the own device starts supplying the VBUS power (power supply) to the other device (step S106). In other words, the own device operates as a USB host.

On the other hand, if the condition of CC voltage ≤ vRd is not satisfied in step S104 (step S104: No), for example, if the own device and the other device are not connected using a USB cable, the process proceeds to step S107. If a specified time has not passed (step S107: No), the process returns to step S104 and repeats the determination as to whether or not the condition of CC voltage ≤ vRd is satisfied. On the other hand, if it is determined in step S107 that the specified time has passed (step S107: Yes), the process proceeds to step S108. Here, the specified time in step S107 corresponds to a timing where the mode of the connection control circuit (CCPHY) 101 is switched between the source mode and the sink mode in the DRP mode.

If the initial setting of the connection control circuit 101 of the own device is not the source (step S101: No), or if it is determined in step S107 that the specified time has passed (step S107: Yes), the switch control circuit 115 controls the switching circuits SW1 and SW2 such that the CC1 terminal and the CC2 terminal are connected to the pull-down resistor Rd (step S108).

Next, the comparator 121 of the operation mode detection circuit 111 compares the voltage (CC voltage) of the CC terminal and a reference voltage vRa (step S109). Here, the reference voltage vRa is used to determine that the own device is the sink, and details thereof are defined in Non-Patent Document 1. If the condition of CC voltage ≥vRa is satisfied (step S110: Yes), that is, if the own device and the other device are connected using a USB cable, and if the operation mode of the other device is the source mode, a sink connection is established (step S111: Yes). Note that the operation mode of the other device is the source mode when the CC terminal of the other device is connected to the pull-up resistor Rp.

Once the sink connection is established, the own device starts receiving the VBUS power from the other device (step S112). In other words, the own device operates as a USB peripheral.

On the other hand, if the condition of CC voltage ≥ vRa is not satisfied in step S110 (step S110: No), for example, if the own device and the other device are not connected using a USB cable, the process proceeds to step S113. If the specified time has not passed (step S113: No), the process returns to step S110, and repeats the determination as to whether or not the condition of CC voltage ≥vRa is satisfied. On the other hand, if it is determined in step S113 that the specified time has passed (step S113: Yes), the process proceeds to step S102 and repeats a similar operation. Here, the specified time in step S113 corresponds to a timing where the mode of the connection control circuit (CCPHY) 101 is switched between the source mode and the sink mode in the DRP mode.

The operation of the DRP mode has been described with reference to the flowchart shown in FIG. 2. However, the connection control circuit (CCPHY) 101 can operate in a source-only mode or a sink-only mode. The source-only mode is a mode in which the own device operates only as the source, and in this case, the CC terminal and the pull-up resistor Rp are fixed in a connected state. In the source-only mode, operations of steps S102 to S106 of the flowchart shown in FIG. 2 are performed. In addition, the sink-only mode is a mode in which the own device operates only as the sink, and in this case, the CC terminal and the pull-down resistor Rd are fixed in the connected state. In the sink-only mode, operations of steps S108 to S112 of the flowchart shown in FIG. 2 are performed.

However, in the related art shown in FIG. 1, the connection control circuit (CCPHY) 101 determines whether the own device is the source side or the sink side by detecting the states of the CC1 terminal and the CC2 terminal. Specifically, the connection control circuit (CCPHY) 101 detects the voltage of the CC terminal, and detects the operation mode (source or sink) of the own device based on the detected voltage of the CC terminal.

Here, the voltage of the CC terminal is detected using the comparator 121 of the operation mode detection circuit 111. However, the comparator 121 continues to consume a predetermined amount of power in the standby mode. Therefore, a problem arises in that power consumption of the CCPHY would become large in the unconnected state.

That is, in the connection control circuit (CCPHY) 101 according to the related art, the comparator 121 is activated and periodically compares the voltage of the CC terminal and the reference voltages vRd and vRa (see steps S104 and S110 of FIG. 2). For example, it is necessary to provide the comparator 121 for each of the reference voltages vRd and vRa. In addition, it is necessary to provide the comparator 121 so as to respectively correspond to the CC1 terminal and the CC2 terminal. Therefore, it is necessary to provide, for example, four comparators for the comparator 121. In addition, it is necessary to supply the reference voltages vRd and vRa to the comparator, making it necessary to provide a reference voltage generation circuit for generating the reference voltages vRd and vRa. Therefore, in the CCPHY according to the related art, a problem arises in that power consumption of the CCPHY would become large in the unconnected state. For example, in the CCPHY according to the related art, steady current of the order of mA is always generated.

The present invention solves the issues of the related art described above. Hereinafter, the connection control circuit according to the present invention will be described.

### First Embodiment

Hereinafter, a first embodiment will be described with reference to the drawings.

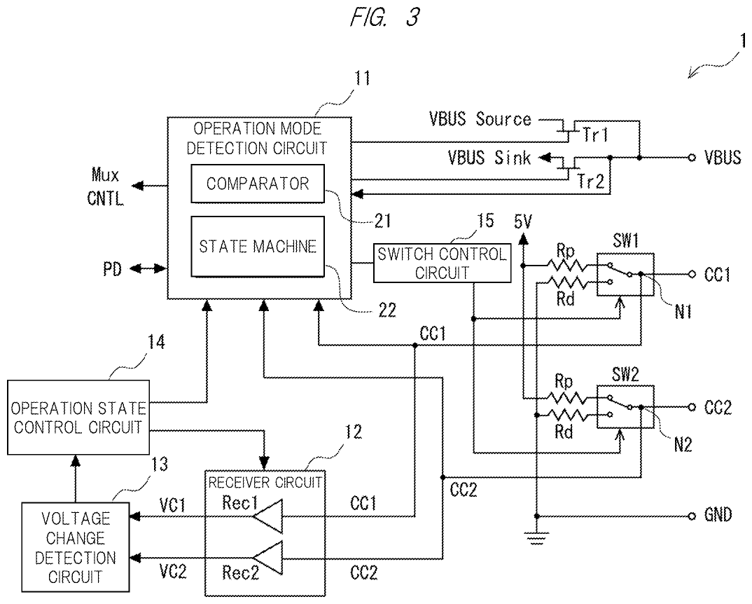

FIG. 3 is a circuit diagram showing a configuration example of a connection control circuit according to the first embodiment. As shown in FIG. 3, a connection control circuit 1 according to the present embodiment comprises a VBUS terminal, a CC1 terminal, a CC2 terminal, a GND terminal, switching circuits SW1 and SW2, a pull-up resistor Rp, a pull-down resistor Rd, an operation mode detection circuit 11, a receiver circuit 12, a voltage change detection circuit 13, an operation state control circuit 14, a switch control circuit 15, and transistors Tr1 and Tr2.

The connection control circuit 1 according to the present embodiment is a connection control circuit conforming to the USB Type-C standard. The connection control circuit 1 according to the present embodiment at least partially configures the CCPHY. For example, in the present embodiment, a circuit including the VBUS terminal, the CC1 terminal, the CC2 terminal, the GND terminal, the switching circuits SW1 and SW2, the pull-up resistor Rp, the pull-down resistor Rd, the operation mode detection circuit 11, the receiver circuit 12, the switch control circuit 15, and the transistors Tr1 and Tr2 may configure the CCPHY, and in this case, the voltage change detection circuit 13 and the operation state control circuit 14 may be provided on a chip that differs from the CCPHY. In addition, in the present embodiment, the CCPHY may be configured so as to include all components of the connection control circuit 1.

As shown in FIG. 3, the CC1 terminal is connected to one end of the pull-up resistor Rp or one end of the pull-down resistor Rd via the switching circuit SW1. The other end of the pull-up resistor Rp is connected to a power supply potential (5V). The other end of the pull-down resistor Rd is connected to a ground potential (GND). Information regarding the voltage CC1 of the CC1 terminal (in other words, the voltage CC1 of a node N1 connected to the CC1 terminal) is supplied to the operation mode detection circuit 11.

Likewise, the CC2 terminal is connected to one end of the pull-up resistor Rp or one end of the pull-down resistor Rd via the switching circuit SW2. The other end of the pull-up resistor Rp is connected to the power supply potential (5V). The other end of the pull-down resistor Rd is connected to the ground potential (GND). Information regarding the voltage CC2 of the CC2 terminal (in other words, the voltage CC2 of a node N2 connected to the CC2 terminal) is supplied to the operation mode detection circuit 11.

Thus, the pull-up resistor Rp, the pull-down resistor Rd, and the switching circuits SW1 and SW2 are provided so as to correspond to each of the CC1 terminal and the CC2 terminal. That is, the connector is reversible in the USB Type-C standard. Therefore, when the own device and the other device are connected using a USB cable, the CC1 terminal or the CC2 terminal of the own device is configured to be connected to the CC1 terminal or the CC2 terminal of the other device. Such a configuration allows the connector to be reversible. Note that the own device is a device on which the connection control circuit (CCPHY) 1 is mounted, and the other device is a device opposite to the own device to be connected thereto via a USB cable.

The switch control circuit 15 controls the switching circuit SW1 and the switching circuit SW2 according to controls of the operation mode detection circuit 11. Specifically, if the own device operates as the source, the switch control circuit 15 controls the switching circuits SW1 and SW2 such that the CC1 terminal and the CC2 terminal are connected to the pull-up resistor Rp, that is, to the power supply potential via the pull-up resistor Rp. In addition, if the own device operates as the sink, the switch control circuit 15 controls the switching circuits SW1 and SW2 such that the CC1 terminal and the CC2 terminal are connected to the pull-down resistor Rd, that is, to the ground potential (GND) via the pull-down resistor Rd.

The operation mode detection circuit 11 detects the operation mode of the own device based on the voltage CC1 of the node N1 connected to the CC1 terminal or on the voltage CC2 of the node N2 connected to the CC2 terminal. Hereinafter, the voltage CC1 of the node N1 connected to the CC1 terminal is also simply referred to as “voltage CC1 of the CC1 terminal”, and the voltage CC2 of the node N2 connected to the CC2 terminal is also simply referred to as “voltage CC2 of the CC2 terminal”. The voltages are also collectively referred to as “voltage CC of the CC terminal”.

If the operation mode of the own device is the source mode, the operation mode detection circuit 11 sets the transistor Tr1 to an ON state and the transistor Tr2 to an OFF state and connects the VBUS terminal and a VBUS source to supply power. On the other hand, if the operation mode of the own device is the sink mode, the operation mode detection circuit 11 sets the transistor Tr2 to an ON state and the transistor Tr1 to an OFF state and connects the VBUS terminal and a VBUS sink.

The operation mode detection circuit 11 comprises comparator 21 and a state machine 22. When the own device and the other device are connected using a USB cable, the operation mode detection circuit 11 uses the comparator 21 to detect the voltage level of the CC terminal. Information regarding the voltage level of the CC terminal detected by the comparator 21 is supplied to the state machine 22. The state machine 22 determines the operation mode of the own device according to the voltage level of the CC terminal. Note that details of the process to determine the operation mode are defined in Non-Patent Document 1.

In the present embodiment, a plurality of comparators may be provided as the comparator 21. For example, there may be provided a comparator for comparing the voltage CC1 of the CC1 terminal and the predetermined reference voltage vRd, a comparator for comparing the voltage CC1 of the CC1 terminal and the predetermined reference voltage VRa, a comparator for comparing the voltage CC2 of the CC2 terminal and the predetermined reference voltage vRd, and a comparator for comparing the voltage CC2 of the CC2 terminal and the predetermined reference voltage vRa.

Here, the reference voltage vRd is used to determine whether or not the own device operates as the source. In addition, the reference voltage vRa is used to determine whether or not the own device operates as the sink. The reference voltages vRd and vRa may be generated by a reference voltage generation circuit (not shown) provided in the operation mode detection circuit 11. Each of the reference voltages vRd and vRa generated by the reference voltage generation circuit is supplied to the respective comparator.

The receiver circuit 12 is provided so as to be connected in parallel to the operation mode detection circuit 11 with respect to the nodes N1 and N2. The receiver circuit 12 is configured to receive the voltages CC1 and CC2 of the respective nodes N1 and N2. Specifically, the receiver circuit 12 is configured such that the voltage CC1 of the node N1 is supplied to an input of a receiver circuit Rec1, and the voltage CC2 of the node N2 is supplied to an input of a receiver circuit Rec2. The receiver circuit 12 can be configured using, for example, a buffer circuit. In addition, the receiver circuit 12 is configured using a circuit that can operate at a lower current than the comparator 21 (that is, a low power-consumption circuit).

In the present embodiment, the pull-up resistor Rp, the pull-down resistor Rd, the switching circuits SW1 and SW2, the comparator 21, and the receiver circuit 12 (Rec1, Rec2) are respectively provided so as to correspond to each of the CC1 terminal and the CC2 terminal.

The voltage change detection circuit 13 detects changes in the voltage levels VC1 and VC2 output from the receiver circuit 12. Specifically, the voltage of the CC terminal changes when the state changes from an unconnected state in which the own device and the other device are not connected to a connected state in which the own device and the other device are connected using a USB cable. The voltage change detection circuit 13 detects the change in the voltage of the CC terminal, that is, the changes in the voltage levels VC1 and VC2 at this time.

For example, if the own device is set as the source, the CC1 terminal and the CC2 terminal are connected to the pull-up resistor Rp. When the own device (source side) is connected to the other device (sink side) in this state, the voltages of the CC1 terminal and the CC2 terminal drop. The voltage change detection circuit 13 detects the changes in the voltages of the CC1 terminal and the CC2 terminal, that is, the changes in the voltage levels VC1 and VC2 at this time.

In addition, for example, if the own device is set as the sink, the CC1 terminal and the CC2 terminal are connected to the pull-down resistor Rd. When the own device (sink side) is connected to the other device (source side) in this state, the voltages of the CC1 terminal and the CC2 terminal rise. The voltage change detection circuit 13 detects the changes in the voltages of the CC1 terminal and the CC2 terminal, that is, the changes in the voltage levels VC1 and VC2 at this time.

Note that, since the receiver circuit 12 may react even with noise, the voltage change detection circuit 13 may be provided with, for example, a circuit for performing a debouncing process. Performing such a debouncing process makes it possible to improve detection accuracy in the voltage change detection circuit 13.

The operation state control circuit 14 controls operation states of the operation mode detection circuit 11 and the receiver circuit 12 according to a detection result of the voltage change detection circuit 13. Specifically, in a first state in which the other device is not connected to the own device, the operation state control circuit 14 sets the receiver circuit 12 to an operating state and the operation mode detection circuit 11 to a stopped state. In addition, in a second state in which the other device is connected to the own device and the voltage change detection circuit 13 has detected a change in the voltage level output from the receiver circuit 12, the operation state control circuit 14 sets the receiver circuit 12 to a stopped state and the operation mode detection circuit 11 to an operating state. Further, in the second state, the operation mode detection circuit 11 detects the operation mode of the own device based on the voltage CC1 of the node N1 connected to the CC1 terminal or the voltage CC2 of the node N2 connected to the CC2 terminal.

In the present embodiment, the operation mode detection circuit 11 and the receiver circuit 12 may be configured so as to be built in the same chip.

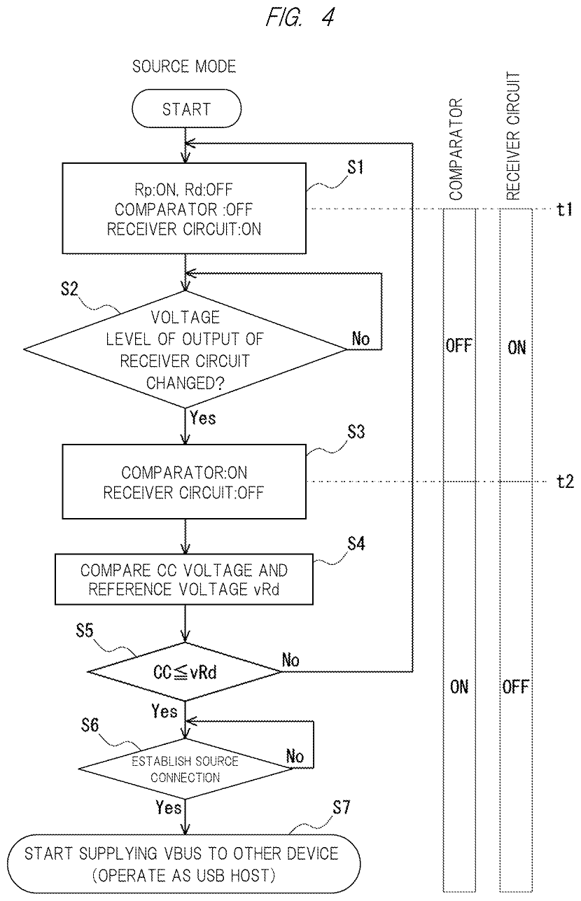

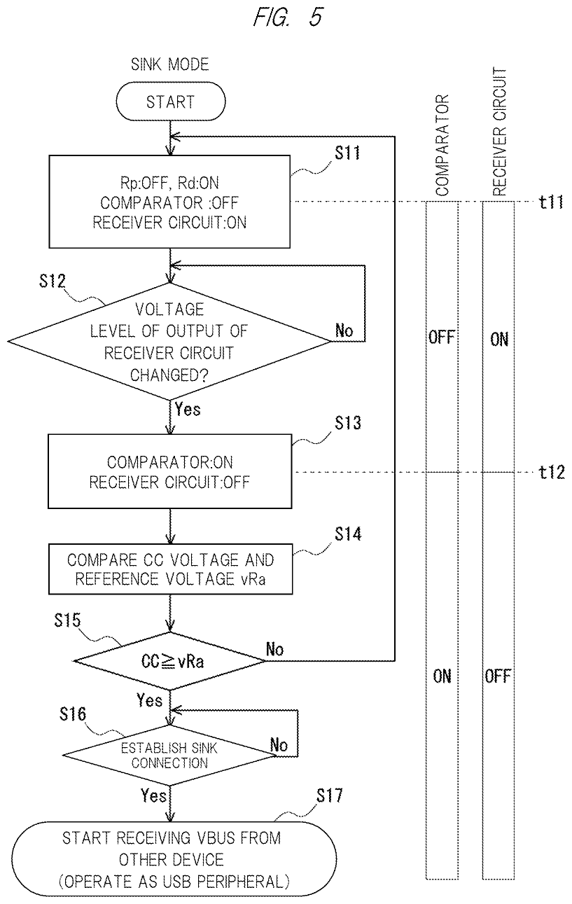

The operation of the connection control circuit according to the present embodiment will now be described with reference to the flowcharts shown in FIGS. 4 and 5. FIG. 4 shows the operation in a case where the operation mode of the connection control circuit 1 is the source mode. FIG. 5 shows the operation in a case where the operation mode of the connection control circuit 1 is the sink mode.

First, the operation in a case where the operation mode of the connection control circuit 1 is the source mode will be described with reference to FIG. 4. The following describes the operation in a case where the state of the own device is changed from the unconnected state to the connected state. First, since the own device operates as the source, the switch control circuit 15 of the connection control circuit 1 controls the switching circuits SW1 and SW2 such that the CC1 terminal and the CC2 terminal are connected to the pull-up resistor Rp. In addition, since the own device is in the unconnected state (first state), the operation state control circuit 14 sets the receiver circuit 12 to an operating state and the operation mode detection circuit (comparator) 11 to a stopped state (step S1).

Then, the voltage change detection circuit 13 determines whether or not the voltage levels VC1 and VC2 output from the receiver circuit 12 have changed (step S2). If the other device is not connected to the own device, the voltage levels VC1 and VC2 output from the receiver circuit 12 do not change (step S2: No). In this case, the voltage change detection circuit 13 continues to determine at regular intervals whether or not the voltage levels VC1 and VC2 output from the receiver circuit 12 have changed.

On the other hand, when the other device is connected to the own device, the voltage levels VC1 and VC2 output from the receiver circuit 12 change (step S2: Yes). When the operation state control circuit 14 detects changes in the voltage levels VC1 and VC2 output from the receiver circuit 12, the operation state control circuit 14 sets the receiver circuit 12 to a stopped state and the operation mode detection circuit (comparator) 11 to an operating state (step S3).

Next, the operation mode detection circuit 11 compares the voltage (CC voltage) of the CC terminal and the reference voltage vRd (step S4). Here, the reference voltage vRd is used to determine that the own device is the source, and details thereof are defined in Non-Patent Document 1.

If the condition of CC voltage ≤ vRd is satisfied (step S5: Yes), that is, if the own device and the other device are connected using a USB cable, and if the operation mode of the other device is the sink mode, the source connection is established (step S6: Yes). On the other hand, if the condition of CC voltage ≤ vRd is not satisfied (step S5: No), the operation is repeated from step S1. Note that the operation mode of the other device is the sink mode when the CC terminal of the other device is connected to the pull-down resistor Rd.

Once the source connection is established, the own device starts supplying the VBUS power (power supply) to the other device (step S7). In other words, the own device operates as a USB host.

In the operation shown in FIG. 4, the operation state control circuit 14 sets the receiver circuit 12 to an operating state and the operation mode detection circuit (comparator) 11 to a stopped state from a timing t1 to a timing t2. Here, power consumption of the receiver circuit 12 is smaller than that of the operation mode detection circuit 11, making it possible to reduce power consumption of the connection control circuit 1 from the timing t1 to the timing t2.

The operation in a case where the operation mode of the connection control circuit 1 is the sink mode will now be described with reference to FIG. 5. First, since the own device operates as the sink, the switch control circuit 15 of the connection control circuit 1 controls the switching circuits SW1 and SW2 such that the CC1 terminal and the CC2 terminal are connected to the pull-down resistor Rd. In addition, since the own device is in the unconnected state (first state), the operation state control circuit 14 sets the receiver circuit 12 to an operating state and the operation mode detection circuit (comparator) 11 to a stopped state (step S11).

Then, the voltage change detection circuit 13 determines whether or not the voltage levels VC1 and VC2 output from the receiver circuit 12 have changed (step S12). If the other device is not connected to the own device, the voltage levels VC1 and VC2 output from the receiver circuit 12 do not change (step S12: No). In this case, the voltage change detection circuit 13 continues to determine at regular intervals whether or not the voltage levels VC1 and VC2 output from the receiver circuit 12 have changed.

On the other hand, when the other device is connected to the own device, the voltage levels VC1 and VC2 output from the receiver circuit 12 change (step S12: Yes). When the operation state control circuit 14 detects changes in the voltage levels VC1 and VC2 output from the receiver circuit 12, the operation state control circuit 14 sets the receiver circuit 12 to a stopped state and the operation mode detection circuit (comparator) 11 to an operating state (step S13).

Next, the operation mode detection circuit 11 compares the voltage (CC voltage) of the CC terminal and the reference voltage vRa (step S14). Here, the reference voltage vRa is used to determine that the own device is the sink, and details thereof are defined in Non-Patent Document 1.

If the condition of CC voltage ≥vRd is satisfied (step S15: Yes), that is, if the own device and the other device are connected using a USB cable, and if the operation mode of the other device is the source mode, the sink connection is established (step S16: Yes). On the other hand, if the condition of CC voltage ≥vRa is not satisfied (step S15: No), the operation is repeated from step S11. Note that the operation mode of the other device is the source mode when the CC terminal of the other device is connected to the pull-up resistor Rp.

Once the sink connection is established, the own device starts receiving the VBUS power from the other device (step S17). In other words, the own device operates as a USB peripheral.

In the operation shown in FIG. 5, the operation state control circuit 14 sets the receiver circuit 12 to an operating state and the operation mode detection circuit (comparator) 11 to a stopped state from a timing t11 to a timing t12. Here, power consumption of the receiver circuit 12 is smaller than that of the operation mode detection circuit 11, making it possible to reduce power consumption of the connection control circuit 1 from the timing t11 to the timing t12.

Note that, in FIGS. 4 and 5, although cases where the operation modes of the connection control circuit 1 are the source mode and the sink mode have been described as examples, the present embodiment can be similarly applied to a case where the operation mode of the connection control circuit 1 is a DRP mode.

As described above, in the present embodiment, the receiver circuit 12 is provided so as to be connected in parallel to the operation mode detection circuit 11. If the own device is in the unconnected state (first state), the receiver circuit 12 is set to an operating state and the operation mode detection circuit 11 is set to a stopped state. That is, if the own device is in the unconnected state, the change in the voltage level of the CC terminal is monitored using the receiver circuit 12 with low power consumption. When the own device is connected to the other device, the receiver circuit 12 is set to a stopped state and the operation mode detection circuit 11 is set to an operating state. For example, while power consumption of the operation mode detection circuit 11 is of the order of mA, power consumption of the receiver circuit 12 is of the order of μA. Therefore, in the unconnected state of the own device, power consumption of the connection control circuit can be reduced.

### Second Embodiment

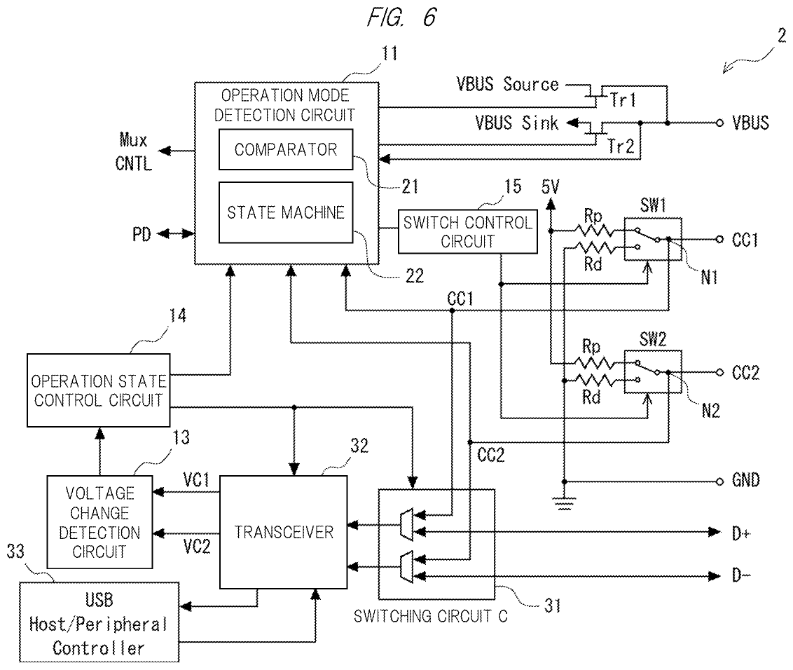

A second embodiment will now be described. FIG. 6 is a circuit diagram showing a configuration example of a connection control circuit according to the second embodiment. A connection control circuit 2 according to the second embodiment shown in FIG. 6 differs from the connection control circuit 1 described for the first embodiment (see FIG. 3) in that it comprises a switching circuit 31, a transceiver 32, and a USB controller 33. Other portions are similar to the connection control circuit 1 described for the first embodiment, and thus, redundant descriptions thereof will be omitted as appropriate.

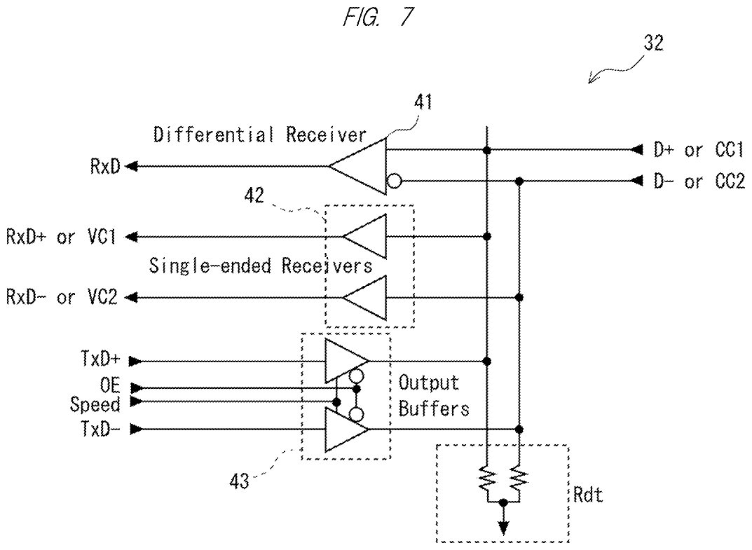

The connection control circuit 2 according to the present embodiment uses single-ended receivers of the transceiver 32 as a receiver circuit instead of being provided with the receiver circuit 12 (see FIG. 3). Here, the transceiver 32 is a “USB 2.0 Transceiver” defined in the USB 2.0 standard, and comprises a circuit configuration shown in FIG. 7.

As shown in FIG. 7, the transceiver 32 comprises one differential receiver 41, two receiver circuits (single-ended receivers) 42, two output buffers 43, and a resistor Rdt. Signal lines D+ and D−, a signal line R×D, signal lines R×D+ and R×D−, and signal lines T×D+ and T×D− are connected to the transceiver 32.

Specifically, the signal lines D+ and D− are connected to an input side of the differential receiver 41, an input side of the receiver circuit 42, and an output side of the output buffer 43. In addition, the signal line R×D is connected to an output side of the differential receiver 41. The signal lines R×D+ and R×D− are connected to an output side of the receiver circuit 42. The signal lines T×D+ and T×D− are connected to an input side of the output buffer 43. The transceiver 32 and the USB controller 33 (see FIG. 6) perform various operations defined in the USB 2.0 standard.

In the present embodiment, the two receiver circuits (single-ended receivers) 42 of the transceiver 32 are used as the receiver circuit. Therefore, in the present embodiment, the switching circuit 31 is provided at a stage prior to the transceiver 32 (see FIG. 6). The switching circuit 31 switches between a case where the voltage CC1 of the CC1 terminal (voltage of node N1) and the voltage CC2 of the CC2 terminal (voltage of node N2) are input to the transceiver 32 and a case where the signal lines D+ and D− are connected. The switching circuit 31 is controlled by the operation state control circuit 14.

In the present embodiment, the operation state control circuit 14 controls the operation states of the operation mode detection circuit 11, the receiver circuit 42 of the transceiver 32, and the switching circuit 31 according to the detection result of the voltage change detection circuit 13. Specifically, in the first state in which the other device is not connected to the own device, the operation state control circuit 14 sets the receiver circuit 42 of the transceiver 32 to an operating state and the operation mode detection circuit 11 to a stopped state. In addition, in the first state, the operation state control circuit 14 controls the switching circuit 31 such that the voltage CC1 of the CC1 terminal (voltage of node N1) and the voltage CC2 of the CC2 terminal (voltage of node N2) are input to the transceiver 32 (receiver circuit 42). In addition, in the first state, it may be set such that the resistor Rdt of the transceiver 32 is turned OFF (that is, such that the resistor Rdt is not connected to the ground potential).

In addition, in the second state in which the other device is connected to the own device and the voltage change detection circuit 13 has detected a change in the voltage level output from the receiver circuit 42, the operation state control circuit 14 sets the receiver circuit 42 of the transceiver 32 to a stopped state and the operation mode detection circuit 11 to an operating state. In addition, in the second state, the operation state control circuit 14 controls the switching circuit 31 such that the signal lines D+ and D− are connected to the transceiver 32. In the second state, the operation mode detection circuit 11 detects the operation mode of the own device based on the voltage CC1 of the node N1 connected to the CC1 terminal or the voltage CC2 of the node N2 connected to the CC2 terminal. In addition, in the second state, the transceiver 32 performs various operations defined in the USB 2.0 standard.

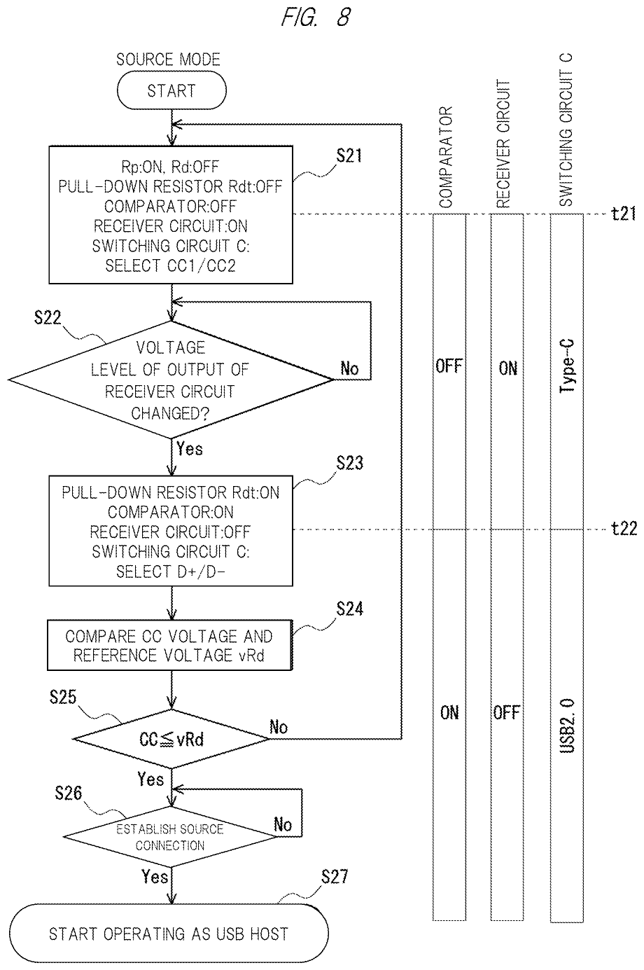

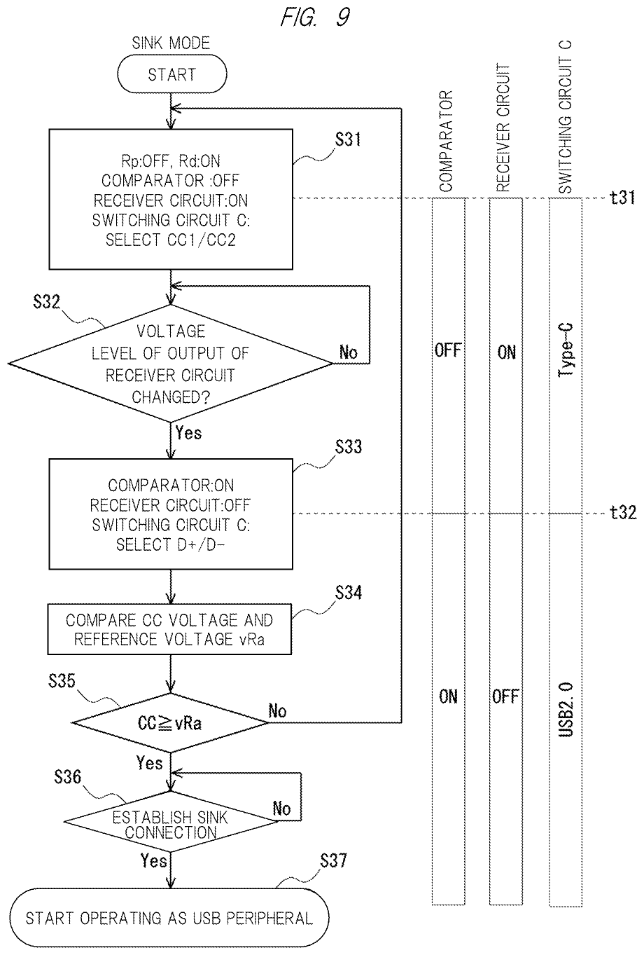

The operation of the connection control circuit according to the present embodiment will now be described with reference to the flowcharts shown in FIGS. 8 and 9. FIG. 8 shows the operation in a case where the operation mode of the connection control circuit 2 is the source mode. FIG. 9 shows the operation in a case where the operation mode of the connection control circuit 2 is the sink mode.

First, the operation in a case where the operation mode of the connection control circuit 2 is the source mode will be described with reference to FIG. 8. The following describes the operation in a case where the state of the own device is changed from the unconnected state to the connected state. First, since the own device operates as the source, the switch control circuit 15 of the connection control circuit 2 controls the switching circuits SW1 and SW2 such that the CC1 terminal and the CC2 terminal are connected to the pull-up resistor Rp. In addition, since the own device is in the unconnected state (first state), the operation state control circuit 14 sets the receiver circuit 42 of the transceiver 32 to an operating state and the operation mode detection circuit (comparator) 11 to a stopped state. In addition, in the first state, the operation state control circuit 14 controls a switching circuit C (31) such that the voltage CC1 of the CC1 terminal (voltage of node N1) and the voltage CC2 of the CC2 terminal (voltage of node N2) are input to the transceiver 32 (receiver circuit 42) (step S21).

Then, the voltage change detection circuit 13 determines whether or not the voltage levels VC1 and VC2 output from the receiver circuit 42 have changed (step S22). If the other device is not connected to the own device, the voltage levels VC1 and VC2 output from the receiver circuit 42 do not change (step S22: No). In this case, the voltage change detection circuit 13 continues to determine at regular intervals whether or not the voltage levels VC1 and VC2 output from the receiver circuit 42 have changed.

On the other hand, when the other device is connected to the own device, the voltage levels VC1 and VC2 output from the receiver circuit 42 change (step S22: Yes). When the operation state control circuit 14 detects changes in the voltage levels VC1 and VC2 output from the receiver circuit 42, the operation state control circuit 14 sets the receiver circuit 42 of the transceiver 32 to a stopped state and the operation mode detection circuit (comparator) 11 to an operating state. In addition, the operation state control circuit 14 controls the switching circuit 31 such that the signal lines D+ and D− are connected to the transceiver 32 (step S23).

Next, the operation mode detection circuit 11 compares the voltage (CC voltage) of the CC terminal and the reference voltage vRd (step S24). Here, the reference voltage vRd is used to determine that the own device is the source, and details thereof are defined in Non-Patent Document 1.

If the condition of CC voltage ≤ vRd is satisfied (step S25: Yes), that is, if the own device and the other device are connected using a USB cable, and if the operation mode of the other device is the sink mode, the source connection is established (step S26: Yes). On the other hand, if the condition of CC voltage ≤vRd is not satisfied (step S25: No), the operation is repeated from step S21. Note that the operation mode of the other device is the sink mode when the CC terminal of the other device is connected to the pull-down resistor Rd.

Once the source connection is established, the own device starts operating as a USB host (step S27).

In the operation shown in FIG. 8, the operation state control circuit 14 sets the receiver circuit 42 to an operating state and the operation mode detection circuit (comparator) 11 to a stopped state from a timing t21 to a timing t22. Here, power consumption of the receiver circuit 42 is smaller than that of the operation mode detection circuit 11, making it possible to reduce power consumption of the connection control circuit 2 from the timing t21 to the timing t22.

In addition, from the timing t21 to the timing t22, the switching circuit C (31) allows the voltage CC1 of the CC1 terminal (voltage of node N1) and the voltage CC2 of the CC2 terminal (voltage of node N2) to be input to the transceiver 32 (receiver circuit 42). In this case, the transceiver 32 is occupied by a USB Type-C host. On the other hand, after the timing t22, the switching circuit C (31) allows the signal lines D+ and D− to be connected to the transceiver 32. In this case, the transceiver 32 is occupied by a USB 2.0 host.

The operation in a case where the operation mode of the connection control circuit 2 is the sink mode will now be described with reference to FIG. 9. First, since the own device operates as the sink, the switch control circuit 15 of the connection control circuit 2 controls the switching circuits SW1 and SW2 such that the CC1 terminal and the CC2 terminal are connected to the pull-down resistor Rd. In addition, since the own device is in the unconnected state (first state), the operation state control circuit 14 sets the receiver circuit 42 of the transceiver 32 to an operating state and the operation mode detection circuit (comparator) 11 to a stopped state. In addition, in the first state, the operation state control circuit 14 controls the switching circuit C (31) such that the voltage CC1 of the CC1 terminal (voltage of node N1) and the voltage CC2 of the CC2 terminal (voltage of node N2) are input to the transceiver 32 (receiver circuit 42) (step S31).

Then, the voltage change detection circuit 13 determines whether or not the voltage levels VC1 and VC2 output from the receiver circuit 12 have changed (step S32). If the other device is not connected to the own device, the voltage levels VC1 and VC2 output from the receiver circuit 42 do not change (step S32: No). In this case, the voltage change detection circuit 13 continues to determine at regular intervals whether or not the voltage levels VC1 and VC2 output from the receiver circuit 42 have changed.

On the other hand, when the other device is connected to the own device, the voltage levels VC1 and VC2 output from the receiver circuit 42 change (step S32: Yes). When the operation state control circuit 14 detects changes in the voltage levels VC1 and VC2 output from the receiver circuit 42, the operation state control circuit 14 sets the receiver circuit 42 of the transceiver 32 to a stopped state and the operation mode detection circuit (comparator) 11 to an operating state. In addition, the operation state control circuit 14 controls the switching circuit 31 such that the signal lines D+ and D− are connected to the transceiver 32 (step S33).

Next, the operation mode detection circuit 11 compares the voltage (CC voltage) of the CC terminal and the reference voltage vRa (step S34). Here, the reference voltage vRa is used to determine that the own device is the sink, and details thereof are defined in Non-Patent Document 1.

If the condition of CC voltage ≥vRa is satisfied (step S35: Yes), that is, if the own device and the other device are connected using a USB cable, and if the operation mode of the other device is the source mode, the sink connection is established (step S36: Yes). On the other hand, if the condition of CC voltage ≥vRd is not satisfied (step S35: No), the operation is repeated from step S31. Note that the operation mode of the other device is the source mode when the CC terminal of the other device is connected to the pull-up resistor Rp.

Once the sink connection is established, the own device starts operating as a USB peripheral (step S37).

In the operation shown in FIG. 9, the operation state control circuit 14 sets the receiver circuit 42 to an operating state and the operation mode detection circuit (comparator) 11 to a stopped state from a timing t31 to a timing t32. Here, power consumption of the receiver circuit 42 is smaller than that of the operation mode detection circuit 11, making it possible to reduce power consumption of the connection control circuit 2 from the timing t31 to the timing t32.

In addition, from the timing t31 to the timing t32, the switching circuit C (31) allows the voltage CC1 of the CC1 terminal (voltage of node N1) and the voltage CC2 of the CC2 terminal (voltage of node N2) to be input to the transceiver 32 (receiver circuit 42). In this case, the transceiver 32 is occupied by a USB Type-C host. On the other hand, after the timing t32, the switching circuit C (31) allows the signal lines D+ and D− to be connected to the transceiver 32. In this case, the transceiver 32 is occupied by a USB 2.0 host.

As described above, the connection control circuit 2 according to the present embodiment uses the single-ended receivers (receiver circuit 42) of the transceiver 32 as a receiver circuit instead of being provided with the receiver circuit 12 (see FIG. 3). Therefore, the number of circuits to be newly provided can be reduced when configuring the connection control circuit 2.

In the foregoing, the invention made by the present inventor has been described in detail based on the embodiments. However, it goes without saying that the present invention is not to be limited to the above-described embodiments and can be variously modified without departing from the scope of the claims.

What is claimed is:

1. A connection control circuit conforming to the USB (Universal Serial Bus) Type-C standard, comprising:
a CC terminal;
an operation mode detection circuit configured to detect an operation mode of a first device based on a voltage of a first node connected to the CC terminal;
a receiver circuit connected in parallel to the operation mode detection circuit and configured to receive the voltage of the first node;
a voltage change detection circuit configured to detect a change in a voltage level output from the receiver circuit; and
an operation state control circuit configured to control operation states of the operation mode detection circuit and the receiver circuit according to a detection result of the voltage change detection circuit,
wherein, in a first state in which a second device is not connected to the first device, the operation state control circuit is configured to set the receiver circuit to an operating state and set the operation mode detection circuit to a stopped state,
wherein, in a second state in which the second device is connected to the first device and the voltage change detection circuit has detected a change in the voltage level output from the receiver circuit, the operation state control circuit is configured to set the receiver circuit to a stopped state and set the operation mode detection circuit to an operating state, and
wherein, in the second state, the operation mode detection circuit is configured to detect the operation mode of the first device based on the voltage of the first node.

2. The connection control circuit according to claim 1,
wherein the operation mode detection circuit comprises:
a comparator configured to compare the voltage of the first node and a predetermined reference voltage; and
a state machine configured to determine the operation mode of the first device according to an output of the comparator.

3. The connection control circuit according to claim 1,
wherein the operation mode detection circuit comprises:
a plurality of comparators each configured to compare a set predetermined reference voltage and the voltage of the first node;
a state machine configured to determine the operation mode of the first device according to an output of the plurality of comparators; and
a reference voltage generation circuit configured to generate respective reference voltages, and supply each of the respective reference voltages to each of the plurality of comparators.

4. The connection control circuit according to claim 2, further comprising a first switching circuit capable of switching between a state in which the first node is connected to a power supply potential via a pull-up resistor, and a state in which the first node is connected to a ground potential via a pull-down resistor.

5. The connection control circuit according to claim 4,
wherein, if the first device operates as a source, the first switching circuit is configured to set the state in which the first node is connected to the power supply potential via the pull-up resistor, and
wherein, if the first device operates as a sink, the first switching circuit is configured to set the state in which the first node is connected to the ground potential via the pull-down resistor.

6. The connection control circuit according to claim 4,
wherein the CC terminal includes a CC1 terminal and a CC2 terminal, and
wherein the pull-up resistor, the pull-down resistor, the first switching circuit, the comparator, and the receiver circuit are each provided so as to correspond to each of the CC1 terminal and the CC2 terminal.

7. The connection control circuit according to claim 1,
wherein the operation mode detection circuit and the receiver circuit are built in the same chip.

8. The connection control circuit according to claim 1,
wherein the receiver circuit is configured using a single-end receiver built in a transceiver circuit conforming to the USB 2.0 standard, and
wherein an input of the single-end receiver is provided with a second switching circuit capable of switching between a state in which the first node is connected and a state in which a USB bus terminal is connected.

9. A connection control method using a connection control circuit conforming to the USB (Universal Serial Bus) Type-C standard, the connection control circuit comprising:
an operation mode detection circuit configured to detect an operation mode of a first device based on a voltage of a first node connected to a CC terminal; and
a receiver circuit connected in parallel to the operation mode detection circuit and configured to receive the voltage of the first node,
wherein the connection control method includes steps in which:
in a first state in which a second device is not connected to the first device, the receiver circuit is set to an operating state and the operation mode detection circuit is set to a stopped state;
in a second state in which a second device is connected to the first device and a change in a voltage level output from the receiver circuit has been detected, the receiver circuit is set to a stopped state and the operation mode detection circuit is set to an operating state; and
in the second state, the operation mode detection circuit detects the operation mode of the first device based on the voltage of the first node, and sets the first device to operate as a source or a sink according to the detected operation mode.

10. The connection control method according to claim 9,
wherein, in the second state, the operation mode detection circuit compares a set predetermined reference voltage and the voltage of the first node, and determines the operation mode of the first device according to a result of the comparison.
